(19) United States
(12) Patent Application Publication
(10) Pub. No.: US 2013/0161075 A1
(43) Pub. Date: Jun. 27, 2013

(54) CONNERTING STRUCTURE OF TOUCH PANEL AND METHOD FOR MANUFACTURING THE SAME

(71) Applicants: Woo Jin LEE, Gyunggi-do (KR); Sang Su HONG, Gyunggi-do (KR)

(72) Inventors: Woo Jin LEE, Gyunggi-do (KR); Sang Su HONG, Gyunggi-do (KR)

(73) Assignee: SAMSUNG ELECTRO-MECHANICS CO., LTD., Gyunggi-do (KR)

(21) Appl. No.: 13/424,439

(22) Filed: Mar. 20, 2012

(30) Foreign Application Priority Data
Dec. 26, 2011 (KR) 1020110142646

(51) Int. Cl. H05K 1/02; H05K 3/00

(52) U.S. Cl. 174/254; 29/846

(57) ABSTRACT

Disclosed herein are a connecting structure of a touch panel and a method for manufacturing the same. The connecting structure of the present invention includes a flexible film; a first electrode formed on one surface of the flexible film; a second electrode formed on the other surface of the flexible film; and a folding part extendedly formed from a side end of the flexible film to be foldably bonded to one surface of the flexible film, wherein the second electrode extends along an outer surface of the folding part so that the first electrode and the second electrode formed at the folding part are disposed on a co-plane.

### CROSS REFERENCE TO RELATED APPLICATION

This application claims the benefit of Korean Patent Application No. 10-2011-0142646, filed on Dec. 26, 2011, entitled “Connecting Structure of Touch Panel and Method for Manufacturing the Same”, which is hereby incorporated by reference in its entirety into this application.

### BACKGROUND OF THE INVENTION

1. Technical Field

The present invention relates to a connecting structure of a touch panel and a method for manufacturing the same.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has been widening the use of computers more and more, it is difficult to efficiently operate products using only a keyboard and mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of a flat panel display such as an electronic organizer, a flat panel display device including a liquid crystal display (LCD) device, a plasma display panel (PDP), an electroluminescence (El), or the like, and an image display device such as a cathode ray tube (CRT) to thereby be used to allow a user to select desired information while viewing the image display device.

In addition, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

Meanwhile, both surfaces of a transparent film of the touch panel are provided with touch electrodes sensing a touch. Accordingly, signals sensed by the touch electrodes are transferred to a control unit to recognize a touch.

In this case, a printed circuit board on which the touch electrodes and the control unit are formed may be connected with both sides of a flexible printed circuit board (FPCB) to transfer the touch sensing signals of the touch electrodes to the control unit through the FPCB.

However, in order to connect the FPCB with the touch electrodes formed on both surfaces of a transparent film, the FPCB is bonded to both surfaces of the transparent film, thereby increasing a manufacturing cost of the FPCB.

### SUMMARY OF THE INVENTION

The present invention has been made in an effort to provide a connecting structure of a touch panel having a single bonding surface at the time of bonding touch electrodes formed on a film with an FPCB and a method for manufacturing the same.

According to a preferred embodiment of the present invention, there is provided a connecting structure of a touch panel, including: a flexible film; a first electrode formed on one surface of the flexible film; a second electrode formed on the other surface of the flexible film; and a folding part extendedly formed from a side end of the flexible film to be foldably bonded to one surface of the flexible film, wherein the second electrode is extendedly formed along an outer surface of the folding part so that the first electrode and the second electrode formed at the folding part are disposed on a co-plane.

The flexible film may include a first film and a second film bonded to each other and one surface of the first film may be provided with the first electrode and the other surface of the second film may be provided with the second electrode.

The folding part may be extendedly formed from the second film.

The folding part may be formed in a rectangular plate shape.

The flexible film may be made of any one of polyethylene terephthalate (PET), polycarbonate (PC), poly methyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, and polystyrene (PS).

The first electrode and the second electrode may be made of any one of copper (Cu), aluminum (Al), gold (Au), silver (Ag), titanium (Ti), palladium (Pd), chromium (Cr), tin (Sn), molybdenum (Mo), and Indium (In).

According to another preferred embodiment of the present invention, there is provided with a method for manufacturing a connecting structure of a touch panel, including: forming a flexible film extendedly formed from a side end of a folding part; forming a first electrode on one surface of the flexible film and forming a second electrode on the other surface thereof, the second electrode extendedly formed to the folding part; and bonding the folding part to one surface of the flexible film by folding the folding part, wherein the first electrode and the second electrode formed at the folding part are disposed on a co-plane.

At the forming of the film, both sides of an end of the flexible film may be cut to form the folding part. The forming of the film may include: forming a first film and a second film; and bonding the second film with the first film to each other.

At the forming of the film, a folding part extending from a side end of the second film may be formed and at the bonding, the first film and the second film may be bonded to each other, excepting for the folding part.

The folding part may be formed in a rectangular plate shape.

The bonding of the folding part may include heat treating applying heat along a line along which the folding part is folded, the folding part being folded after the heat treating is performed.

At the heat treating, heat may be applied through a heating rod.

The flexible film may be made of any one of polyethylene terephthalate (PET), polycarbonate (PC), poly methyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, and polystyrene (PS).

The first electrode and the second electrode may be made of any one of copper (Cu), aluminum (Al), gold (Au), silver (Ag), titanium (Ti), palladium (Pd), chromium (Cr), tin (Sn), molybdenum (Mo), and Indium (In).

### BRIEF DESCRIPTION OF THE DRAWINGS

FIG. 1 is a plan view showing a connecting structure of a touch panel according to a first preferred embodiment of the present invention;

FIG. 2 is a cross-sectional view taken along the line A-A′ of FIG. 1;

FIG. 3 is a plan view showing a connecting structure of a touch panel according to a second preferred embodiment of the present invention;

FIG. 4 is a cross-sectional view taken along the line B-B′ of FIG. 3;

FIG. 5 is a flow chart showing a method for manufacturing a connecting structure of a touch panel according to a third preferred embodiment of the present invention;

FIGS. 6 to 9 are plan views sequentially showing a process of a method for manufacturing the connecting structure the touch panel according to the third preferred embodiment of the present invention;

FIG. 10 is a flow chart showing a method for manufacturing a connecting structure of a touch panel according to a fourth preferred embodiment of the present invention; and

FIGS. 11 to 13 are plan views sequentially showing a process of a method for manufacturing a connecting structure of a touch panel according to the fourth preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In addition, the present invention may be modified in various different ways and is not limited to the preferred embodiments provided in the present description. Further, in describing the present invention, a detailed description of related known functions or configurations will be omitted so as not to obscure the subject of the present invention.

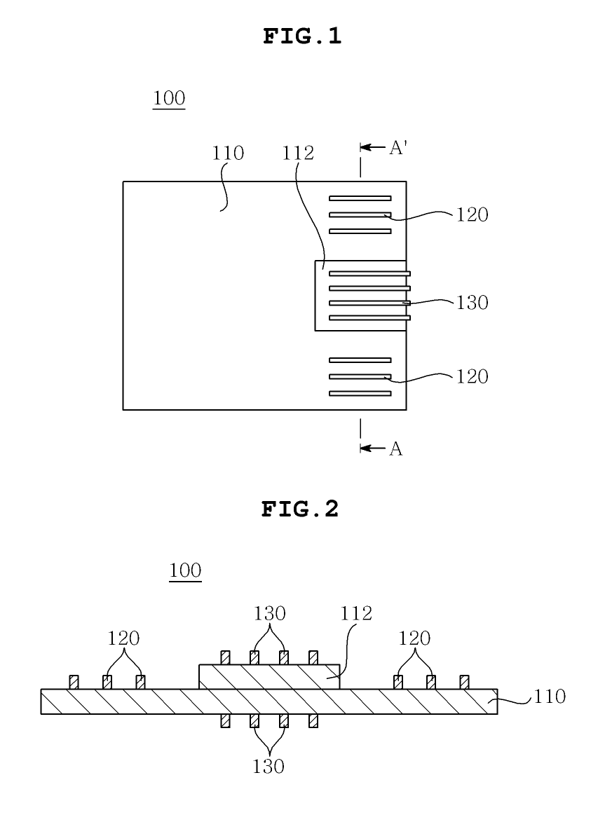

FIG. 1 is a plan view showing a connecting structure of a touch panel according to a first preferred embodiment of the present invention and FIG. 2 is a cross-sectional view taken along the line A-A′ of FIG. 1.

Referring to FIG. 1, a connecting structure 100 according to a first preferred embodiment of the present invention includes a flexible film 110, a first electrode 120, a second electrode 130, and a folding part 112.

Hereinafter, referring to FIGS. 1 and 2, the connecting structure 100 according to the first preferred embodiment of the present invention will be described in detail.

Referring first to FIGS. 1 and 2, a flexible film 110 provides a support on which the first electrode 120 and the second electrode 130 are formed.

Here, the flexible film 110 may be made of any one of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), and biaxially oriented polystyrene (BOPS; containing K resin), but is not necessarily limited thereto.

Meanwhile, in order to activate both surfaces of the flexible film 110, a high frequency treatment or a primer treatment may be performed. An adhesion between the flexible film 110 and the first electrode 120 and the second electrode 130 may be improved by activating both surfaces of the flexible film 110.

Referring to FIGS. 1 and 2, the first electrode 120 and the second electrode 130 that are the touch electrode are each formed on one surface and the other surface of the flexible film 110.

Here, the first electrode 120 is configured of a sensing electrode and the second electrode 130 is configured of the driving electrode 130.

In this case, the first electrode 120 and the second electrode 130 generate signals when a user is touched, thereby serving to recognize touched coordinates by a controller. In this case, when voltage is applied to the second electrode 130, electric field is formed in the first electrode 120 through the second electrode 130 and when an object is touched to the first electrode 120, charge amount is reduced, such that it is determined that the object is touched.

Further, the first electrode 120 and the second electrode 130 may be made of conductive polymer, metal oxide, metal, or metal mesh.

First, the conductive polymer has excellent flexibility and a simple coating process. Here, an example of the conductive polymer may include poly-3,4-ethylenedioxythiophene/polystyrenesulfonate (PEDOT/PSS), polyaniline, polyacetylene, or polyphenylenevinylene.

In addition, the metal oxide is made of indium-tin oxide.

Further, the metal mesh may be formed of any one or more among copper (Cu), aluminum (Al), gold (Au), silver (Ag), titanium (Ti), palladium (Pd), chromium (Cr), tin (Sn), molybdenum (Mo) and indium (In).

Further, the metal mesh 140 may be formed in a mesh pattern using copper (Cu), aluminum (Al), gold (Au), silver (Ag), titanium (Ti), palladium (Pd), chromium (Cr), or a combination thereof.

In this case, the first electrode 120 and the second electrode 130 may be formed by a plating process or an evaporation process.

Meanwhile, when the first electrode 120 and the second electrode 130 are made of copper (Cu), the surfaces of the first electrode 120 and the second electrode 130 may be blackened. Here, the black-oxide treatment indicates treatment in which Cu₂O or CuO is precipitated by oxidizing the surface of the touch electrode, wherein the Cu₂O is brown and is thus referred to as a brown oxide and the CuO is black and is thus referred to as a black oxide. As described above, the surface of the touch electrode is black-oxide treated to prevent light from being reflected, thereby making it possible to improve visibility of the connecting structure 100.

Further, a line width of the touch electrode is set to be 7 μm or less and a pitch thereof is set to to be 900 μm or less, thereby making it possible to improve visibility. However, the line width and the pitch of the connecting structure 100 of the present invention is not limited thereto.

Meanwhile, the first electrode 120 and the second electrode 130 may also be made of metal silver formed by exposing and developing a silver salt emulsion layer, in addition to the above-mentioned metals.

Referring to FIGS. 1 and 2, the folding part 112 is extendedly formed from the side end of the flexible film 110 and foldably bonded to one surface of the flexible film 110.

Here, the side end of the flexible film 110 may be an extending direction of the second electrode 130.

In addition, the second electrode 130 is extendedly formed along an outer surface of the folding part 112 so that the first electrode 120 and the second electrode 130 formed on the folding part 112 are disposed on a co-plane.

Describing in more detail as an example, only a portion of the folding part 112 extending from the flexible film 110 is folded and is bonded to a top surface of the flexible film 110 by an adhesive. As a result, the second electrode 130 formed on the outer surface of the folding part 112 may be located on the same surface as the first electrode 120 formed on the top surface of the flexible film 110. In this case, the first electrode 120 and the second electrode 130 are formed in a parallel direction with each other and a central portion thereof may be provided with the second electrode 130 and both sides thereof may be provided with the first electrode 120. Therefore, the flexible printed circuit board (FPCB) is bonded to a portion at which the first electrode 120 and the second electrode 130 are formed on a co-plane, such that the first electrode 120 and the second electrode 130 may be electrically connected with the flexible circuit board. In particular, it is possible to bond the flexible printed circuit board (FPCB) with the single surface, thereby reducing the difficulty in the bonding process and reducing the manufacturing time.

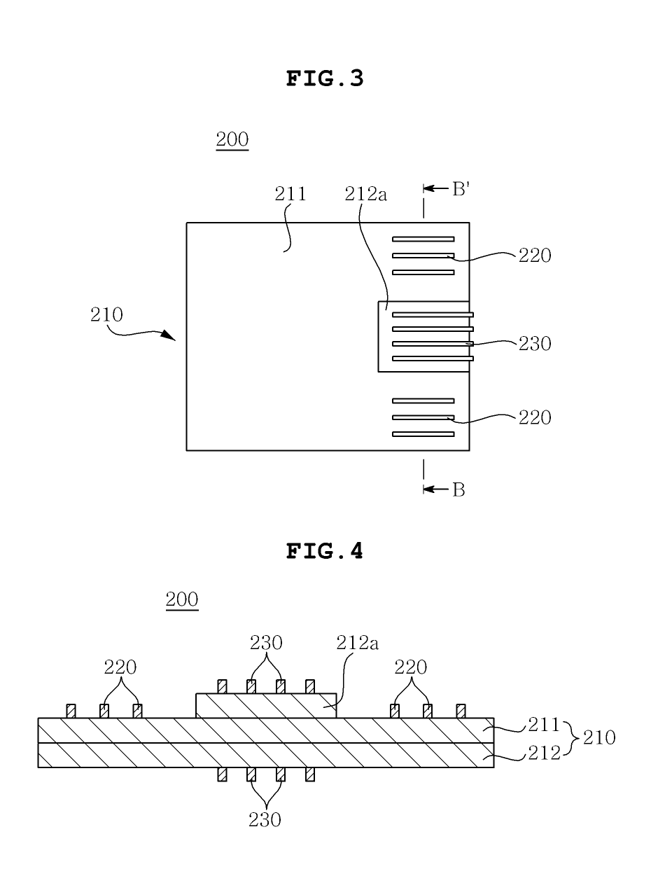

FIG. 3 is a plan view showing a connecting structure of a touch panel according to a second preferred embodiment of the present invention and FIG. 4 is a cross-sectional view taken along the line B-B′ of FIG. 3.

Referring to FIG. 3, a connecting structure 200 of a touch panel according to a second preferred embodiment of the present invention includes a flexible film, the first electrode 120, the second electrode 130, and a folding part 212a.

When comparing the connecting structure 200 of the touch panel according to the preferred embodiment of the present invention with the connecting structure of the touch panel according to a first preferred embodiment of the present invention, they have a difference in that the flexible film 210 is provided in plural and the first electrode 120 and the second electrode 130 are each formed on the plurality of flexible films 210. Therefore, the second preferred embodiment of the present invention briefly describes the repeated contents with the first preferred embodiment of the present invention and the difference thereof will be mainly described. In addition, it is to be noted that the overlapping components of the second preferred embodiment of the present invention and the first preferred embodiment of the present invention are denoted by the same reference numerals.

Hereinafter, referring to FIGS. 3 and 4, the method for manufacturing a connecting structure of a touch panel according to the second preferred embodiment of the present invention will be described in more detail.

Referring first to FIGS. 3 and 4, a flexible film 210 is configured to include a first film 211 and a second film 212. Here, the first film 211 and the second film 212 may be made of the same material and the other surface of the first film 211 is bonded to one surface of the second film 212 by an adhesive.

Further, one surface of the first film 211 is provided with the first electrode 120 and the other surface of the second film 212 is provided with the second electrode 130.

In addition, the folding part 212a is extendedly formed from the side end of the second film 212 and the second electrode 130 is extendedly formed on the outer surface of the folding part 212a.

In this case, the folding part 212a is folded so as to be bonded to one surface of the first film 211, such that the first electrode 120 and the second electrode 130 formed at the folding part 212a are disposed at the co-plane.

Therefore, the flexible printed circuit board (FPCB) is bonded to a portion at which the first electrode 120 and the second electrode 130 are formed on a co-plane, such that the first electrode 120 and the second electrode 130 may be electrically connected with the flexible printed circuit board. In particular, it is possible to bond the flexible printed circuit board (FPCB) with the single surface, thereby reducing the difficulty in the bonding process and reducing the manufacturing time.

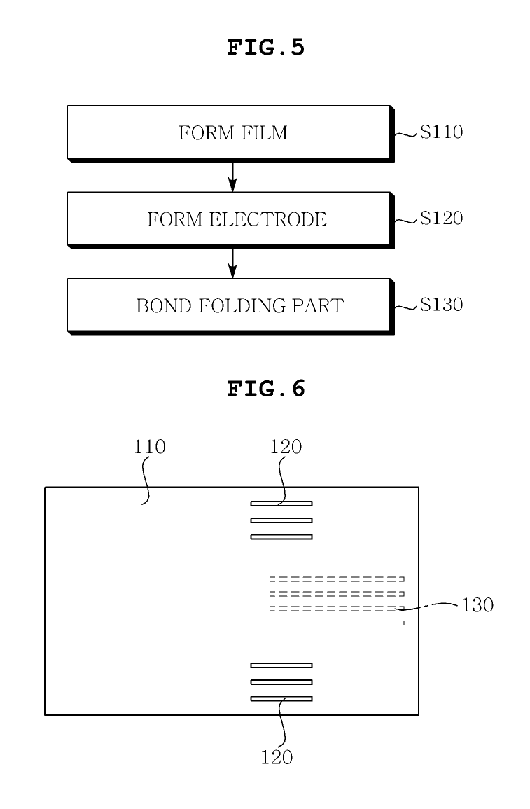

FIG. 5 is a flow chart showing a method for manufacturing a connecting structure of a touch panel according to a third preferred embodiment of the present invention.

As shown in FIG. 5, the method for manufacturing a connecting structure of a touch panel according to the preferred embodiment of the present invention includes forming a film (S110), forming an electrode (S120), and bonding a folding part (S130).

The method for manufacturing a connecting structure of a touch panel according to the preferred embodiment of the present invention relates to the method for manufacturing the connecting structure 100 of the touch panel according to the first preferred embodiment of the present invention.

In addition, the second preferred embodiment of the present invention briefly describes the repeated contents with the first preferred embodiment of the present invention and the difference thereof will be mainly described.

Further, the same components are denoted by the same reference numerals.

FIGS. 6 to 9 are plan views sequentially showing a process of a method for manufacturing the connecting structure of the touch panel according to the third preferred embodiment of the present invention.

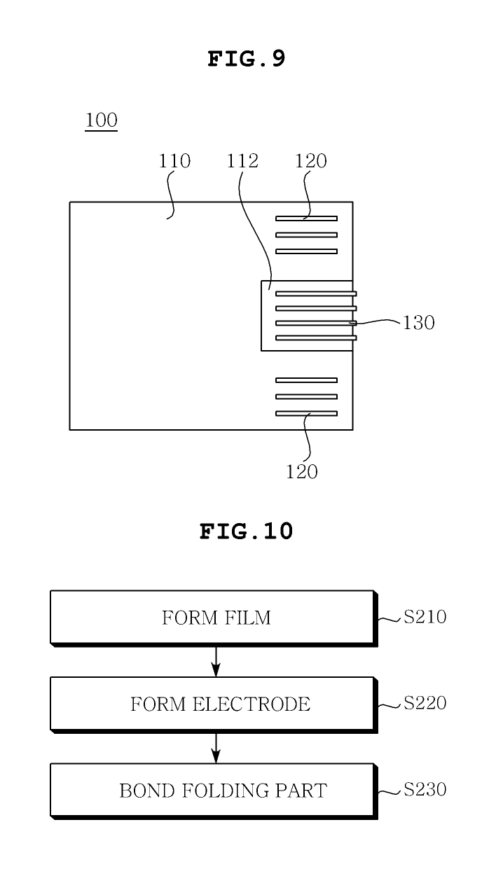

Hereinafter, referring to FIGS. 5 and 9, a method for manufacturing a connecting structure of a touch panel according to a third preferred embodiment of the present invention will be described in more detail.

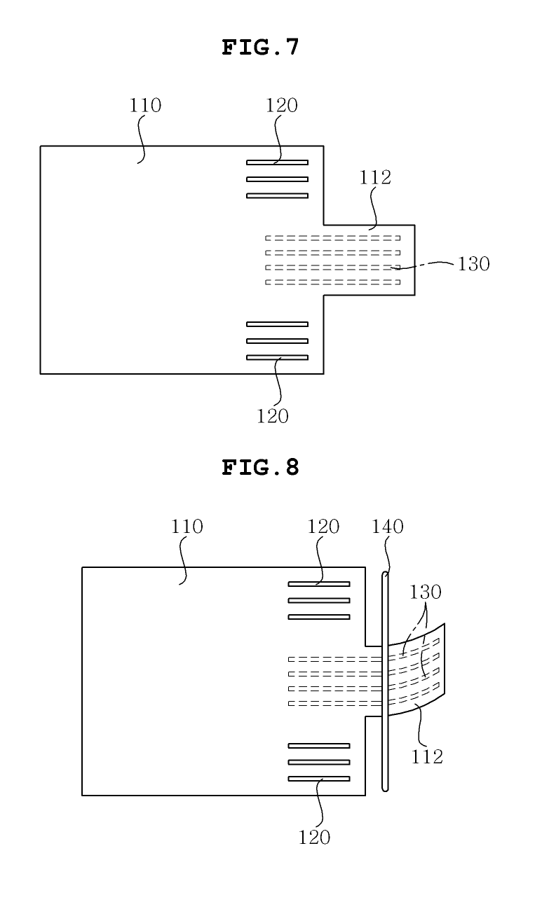

Referring to FIGS. 6 and 7, the forming of the film (S110) forms the flexible film 110 in which the folding part 112 is extendedly formed from the side end thereof Here, the forming of the film (S110) may cut the flexible film 110 to form the folding part 112.

In addition, the flexible film 110 may be made of any one of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), and biaxially oriented polystyrene (BOPS; containing K resin), but is not necessarily limited thereto.

Further, the folding part 112 is extendedly formed from the side end of the flexible film 110 and may be formed in a rectangular plate shape. However, the shape of the folding part 112 according to the third preferred embodiment of the present invention is not limited to the rectangular plate shape. For example, the side end of the folding part 112 may be an extending direction of the second electrode 130.

Meanwhile, in order to activate both surfaces of the flexible film 110, a high frequency treatment or a primer treatment may be performed. An adhesion between the flexible film 110 and the first electrode 120 and the second electrode 130 may be improved by activating both surfaces of the flexible film 110.

Referring to FIG. 6, the forming of the electrode (S120) forms the first electrode 120 on one surface of the flexible film 110 and forms the second electrode 130 on the other surface thereof. In this case, the second electrode 130 is extendedly formed to the folding part 112. Here, for example, one surface of the flexible film 110 may be a top surface and the other surface may be a bottom surface.

Further, the first electrode 120 may be configured of the sensing electrode and the second electrode 130 may be configured of the driving electrode 130. In this case, the first electrode 120 and the second electrode 130 generate signals when a user is touched, thereby serving to recognize touched coordinates by a controller. In this case, when voltage is applied to the second electrode 130, electric field is formed in the first electrode 120 through the second electrode 130 and when an object is touched to the first electrode 120, charge amount is reduced, such that it is determined that the object is touched.

Further, the first electrode 120 and the second electrode 130 may be made of conductive polymer, metal oxide, metal, or metal mesh.

First, the conductive polymer has excellent flexibility and a simple coating process. Here, an example of the conductive polymer may include poly-3,4-ethylenedioxythiophene/polystyrenesulfonate (PEDOT/PSS), polyaniline, polyacetylene, or polyphenylenevinylene.

In addition, the metal oxide is made of indium-tin oxide.

Further, the metal mesh may be formed of any one or more among copper (Cu), aluminum (Al), gold (Au), silver (Ag), titanium (Ti), palladium (Pd), chromium (Cr), tin (Sn), molybdenum (Mo) and indium (In).

Further, the first electrode 120 and the second electrode 130 made of conductive polymer, metal oxide, or metal may be formed by a dry process, a wet process, or a direct patterning process.

Here, the dry process means sputtering, evaporation, or the like, the wet process means dip coating, spin coating, roll coating, spray coating, or the like, and the direct patterning process means screen printing, gravure printing, inkjet printing, or the like.

Further, the metal mesh may be formed in a mesh pattern using copper (Cu), aluminum (Al), gold (Au), silver (Ag), titanium (Ti), palladium (Pd), chromium (Cr), or a combination thereof.

In this case, the first electrode 120 and the second electrode 130 may be formed by a plating process or an evaporation process.

Meanwhile, when the first electrode 120 and the second electrode 130 are made of copper (Cu), the surfaces of the first electrode 120 and the second electrode 130 may be blackened. Here, the black-oxide treatment indicates treatment in which Cu₂O or CuO is precipitated by oxidizing the surface of the touch electrode, wherein the Cu₂O is brown and is thus referred to as a brown oxide and the CuO is black and is thus referred to as a black oxide. As described above, the surface of the touch electrode is black-oxide treated to prevent light from being reflected, thereby making it possible to improve visibility of the connecting structure 100.

Further, a line width of the touch electrode is set to be 7 μm or less and a pitch thereof is set to be 900 μm or less, thereby making it possible to improve visibility. However, the line width and the pitch of the connecting structure of the present invention is not limited thereto.

Meanwhile, the first electrode 120 and the second electrode 130 may also be made of metal silver formed by exposing and developing a silver salt emulsion layer, in addition to the above-mentioned metals.

Referring to FIGS. 8 and 9, the bonding of the folding part (S130) folds the folding part 112 so as to be bonded to one surface of the flexible film 110. Therefore, the first electrode 120 and the second electrode 130 formed on the folding part 112 are disposed on the co-plane.

Here, the bonding of the folding part (S130) may further include heat treating applying heat to the flexible film 110 along a folding line along which the folding part 112 is folded. Therefore, the folding part 112 may be easily folded by applying heat around the folded line. In this case, heat may be applied to the folded line through the heating rod 140.

As a result, the first electrode 120 and the second electrode 130 are formed on the co-plane by manufacturing the connecting structure of the touch panel according to the third preferred embodiment of the present invention by the above-mentioned method.

Therefore, the first electrode 120 and the second electrode 130 may be bonded to each other on the single surface by the flexible printed circuit board (FPCB), or the like. Thereby, the difficulty in the bonding process may be lowered and the manufacturing time may be reduced.

FIG. 10 is a diagram sequentially showing a process of a method for manufacturing a touch panel according to a fourth preferred embodiment of the present invention.

As shown in FIG. 10, the method for manufacturing a connecting structure of a touch panel according to the embodiment of the present invention includes forming a film (S210), forming an electrode (S220), and bonding a folding part (S230).

The method for manufacturing a connecting structure of a touch panel according to the embodiment of the present invention relates to the method for manufacturing the connecting structure 200 of the touch panel according to the second embodiment of the present invention.

When comparing the connecting structure of the touch panel according to the third embodiment of the present invention with the connecting structure of the touch panel, they have a difference in that the flexible film 210 is provided in plural and the first electrode 120 and the second electrode 130 are each formed on the plurality of flexible films 210.

In addition, the third preferred embodiment of the present invention briefly describes the repeated contents with the first preferred embodiment of the present invention and the difference thereof will be mainly described. In addition, it is to be noted that the overlapping components of the first embodiment of the present invention to the third embodiment of the present invention are denoted by the same reference numerals.

Hereinafter, referring to FIGS. 10 and 13, a method for manufacturing a connecting structure of a touch panel according to a fourth preferred embodiment of the present invention will be described in more detail.

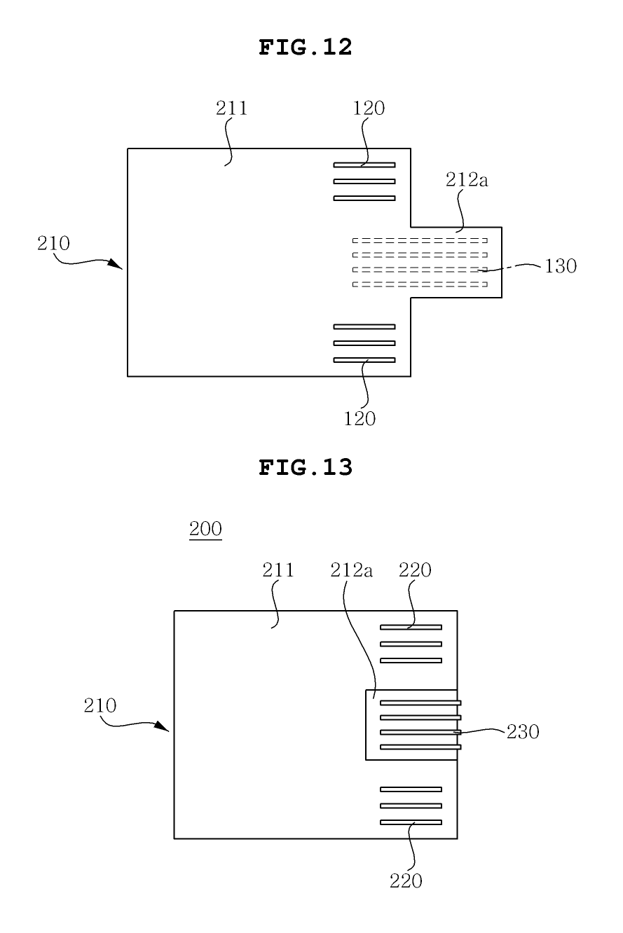

Referring to FIGS. 10 and 12, the forming of the film (S210) forms the flexible film 210 in which the folding part 212a is extendedly formed from the side end thereof.

Here, the process of forming the film (S210) may include forming the first film 211 and the second film 212 and bonding the second film 212 and the first film 211 to each other.

Therefore, the flexible film 210 is configured to include the first film 211 and the second film 212.

In addition, the forming of the film forms the folding part 212a on the second film 212 but forms the folding part 212a in an extending direction from the side end of the second film 212. In this case, the folding part 212a may be formed by cutting the second film 212. Further, the folding part 212a may be formed in a rectangular plate shape.

Further, the bonding bonds the first film 211 and the second film 212 to each other by an adhesive, excepting for the folding part 212a.

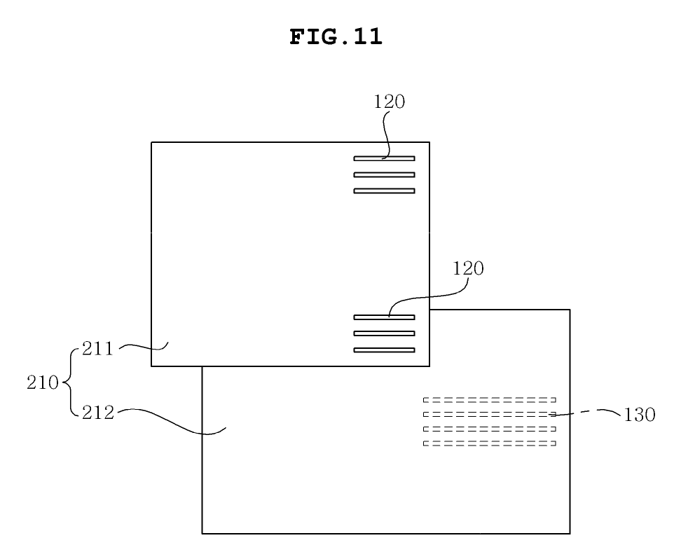

Referring to FIGS. 10 to 12, the forming of the electrode (S220) forms the first electrode 120 on one surface of the first film 211 of the flexible film 210 and forms the second electrode 130 on the other surface of the second film 212. In this case, the second electrode 130 is extendedly formed to the folding part 212a.

Further, the first electrode 120 may be configured of the sensing electrode and the second electrode 130 may be configured of the driving electrode 130. In this case, the first electrode 120 and the second electrode 130 generate signals when a user is touched, thereby serving to recognize touched coordinates by a controller. In this case, when voltage is applied to the second electrode 130, electric field is formed in the first electrode 120 through the second electrode 130 and when an object is touched to the first electrode 120, charge amount is reduced, such that it is determined that the object is touched.

Further, the first electrode 120 and the second electrode 130 may be made of conductive polymer, metal oxide, metal, or metal mesh.

First, the conductive polymer has excellent flexibility and a simple coating process. Here, an example of the conductive polymer may include poly-3,4-ethylenedioxythiophene/polystyrenesulfonate (PEDOT/PSS), polyaniline, polyacetylene, or polyphenylenevinylene.

In addition, the metal oxide is made of indium-thin oxide.

Further, the metal may be formed of any one of copper (Cu), aluminum (Al), gold (Au), silver (Ag), titanium (Ti), palladium (Pd), chromium (Cr), tin (Sn), molybdenum (Mo), indium (In), or a combination thereof.

Meanwhile, the metal mesh 140 may be formed in a mesh pattern using copper (Cu), aluminum (Al), gold (Au), silver (Ag), titanium (Ti), palladium (Pd), chromium (Cr), or a combination thereof.

Further, a line width of the touch electrode is set to be 7 μm or less and a pitch thereof is set to be 900 μm or less, thereby making it possible to improve visibility. However, the line width and the pitch of the connecting structure 200 of the present invention are not limited thereto.

Meanwhile, the first electrode 120 and the second electrode 130 may also be made of metal silver formed by exposing and developing a silver salt emulsion layer, in addition to the above-mentioned metals.

Referring to FIGS. 10 and 13, the bonding of the folding part (S230) folds the folding part 212a so as to be bonded to one surface of the first film 211. Therefore, the first electrode 120 formed on one surface of the first film 211 and the second electrode 130 formed on the folding part 112a are disposed on the co-plane.

Here, the bonding of the folding part (S230) may further include heat treating applying heat to the flexible film 210 along a folded line along which the folding part 212a is folded. Therefore, the folding part 212a may be easily folded by applying heat around the folded line. In this case, heat may be applied to the folded line through the heating rod 140.

As a result, the first electrode 120 and the second electrode 130 are formed on the co-plane by manufacturing the connecting structure of the touch panel according to a fourth preferred embodiment of the present invention by the above-mentioned method.

Therefore, the first electrode 120 and the second electrode 130 may be bonded to each other on the single surface by the flexible printed circuit board (FPCB), or the like. Thereby, the difficulty in the bonding process may be lowered and the manufacturing time may be reduced.

According to the preferred embodiments of the present invention, the touch electrodes formed on the film has the single bonding surface at the time of connecting with the touch electrodes, thereby reducing the difficulty in the bonding process and reducing the manufacturing time.

Although the preferred embodiments of the present invention have been disclosed for illustrative purposes, they are for specifically explaining the present invention and thus a connecting to structure of a touch panel and a method for manufacturing the same according to the present invention are not limited thereto, but those skilled in the art will appreciate that various modifications, additions and substitutions are possible, without departing from the scope and spirit of the invention as disclosed in the accompanying claims.

In addition, any and all modifications, variations or equivalent arrangements should be considered to be within the scope of the invention, and the detailed scope of the invention will be disclosed by the accompanying claims.

What is claimed is:

1. A connecting structure of a touch panel, comprising:
a flexible film;
a first electrode formed on one surface of the flexible film;
a second electrode formed on the other surface of the flexible film; and
a folding part extendedly formed from a side end of the flexible film to be foldably bonded to one surface of the flexible film,
wherein the second electrode is extendedly formed along an outer surface of the folding part so that the first electrode and the second electrode formed at the folding part are disposed on a co-plane.

2. The connecting structure of a touch panel as set forth in claim 1, wherein the flexible film includes a first film and a second film bonded to each other and one surface of the first film is provided with the first electrode and the other surface of the second film is provided with the second electrode.

3. The connecting structure of a touch panel as set forth in claim 2, wherein the folding part is extendedly formed from the second film.

4. The connecting structure of a touch panel as set forth in claim 1, wherein the folding part is formed in a rectangular plate shape.

5. The connecting structure of a touch panel as set forth in claim 1, wherein the flexible film is made of any one of polyethylene terephthalate (PET), polycarbonate (PC), poly methyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, and polystyrene (PS).

6. The connecting structure of a touch panel as set forth in claim 1, wherein the first electrode and the second electrode are made of any one of copper (Cu), aluminum (Al), gold (Au), silver (Ag), titanium (Ti), palladium (Pd), chromium (Cr), tin (Sn), molybdenum (Mo), and Indium (In).

7. A method for manufacturing a connecting structure of a touch panel, comprising:
forming a flexible film extendedly formed from a side end of a folding part;
forming a first electrode on one surface of the flexible film and forming a second electrode on the other surface thereof, the second electrode extendedly formed to the folding part; and
bonding the folding part to one surface of the flexible film by folding the folding part,
wherein the first electrode and the second electrode formed at the folding part are disposed on a co-plane.

8. The method as set forth in claim 7, wherein at the forming of the film, both sides of an end of the flexible film are cut to form the folding part.

9. The method as set forth in claim 7, wherein the forming of the film includes:
forming a first film and a second film; and
bonding the second film and the first film to each other.

10. The method as set forth in claim 9, wherein at the forming of the film, a folding part extending from a side end of the second film is formed and at the bonding, the first film and the second film are bonded to each other, excepting for the folding part.

11. The method as set forth in claim 7, wherein the folding part is formed in a rectangular plate shape.

12. The method as set forth in claim 7, wherein the bonding of the folding part includes heat treating applying heat along a line along which the folding part is folded, the folding part being folded after the heat treating is performed.

13. The method as set forth in claim 12, wherein at the heat treating, heat is applied through a heating rod.

14. The method as set forth in claim 7, wherein the flexible film is made of any one of polyethylene terephthalate (PET), polycarbonate (PC), poly methyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, and polystyrene (PS).

15. The method as set forth in claim 7, wherein the first electrode and the second electrode are made of copper (Cu), aluminum (Al), gold (Au), silver (Ag), titanium (Ti), palladium (Pd), chromium (Cr), tin (Sn), molybdenum (Mo), and Indium (In).
